(19) United States
(12) Patent Application Publication
(10) Pub. No.: US 2011/0092054 A1
(43) Pub. Date: Apr. 21, 2011

(54) Methods for fixing graphene defects using a laser beam and methods of manufacturing an electronic device

(75) Inventors: Sun-ae Seo, Hwaseong-si (KR); Dong-chul Kim, Suwon-si (KR); Yun-sung Woo, Suwon-si (KR); Hyun-jong Chung, Hwaseong-si (KR); Jin-seong Heo, Suwon-si (KR)

(73) Assignee: Samsung Electronics Co., Ltd.

(21) Appl. No.: 12/805,982

(22) Filed: Aug. 27, 2010

(30) Foreign Application Priority Data
Oct. 20, 2009 (KR) 10-2009-0099833

(51) Int. Cl. H01L 21/26

(52) U.S. Cl. 438/473; 257/E21.328

(57) ABSTRACT

Methods of fixing graphene using a laser beam and methods of manufacturing an electronic device are provided, the method of fixing graphene includes fixing a defect of a graphene nanoribbon by irradiating the laser beam onto the graphene nanoribbon.

### CROSS-REFERENCE TO RELATED APPLICATIONS

This application claims the benefit of priority under 35 U.S.C. §119 from Korean Patent Application No. 10-2009-0099833, filed on Oct. 20, 2009, in the Korean Intellectual Property Office, the disclosure of which is incorporated herein in its entirety by reference.

### BACKGROUND

1. Field

Example embodiments relate to methods for fixing defects in graphene, or a graphene nanoribbon, using a laser beam. Other example embodiments relate to methods of manufacturing an electronic device that includes fixing defects in graphene, or a graphene nanoribbon, using a laser beam.

2. Description of the Related Art

Graphene is a hexagonal single-layer structure formed of carbon atoms. Graphene is chemically very stable. Graphene has characteristics of a semi-metal in which a conduction band and a valence band overlap each other only at one point, a Dirac point. Also, 2-dimensional ballistic transport occurs in graphene. 2-dimensional ballistic transport of a charge in a medium means that a charge is transported in a medium without substantially any resistance due to scattering. As such, the mobility of charges in graphene is very high.

When graphene nanoribbons (GNRs) having a width less than 10-nm are manufactured, a band gap is formed in the GNRs. It is possible to manufacture graphene nanoribbon field effect transistors (GNR FETs) capable of operating at a room temperature. Etching damage may occur in edges of the GNRs during the etching of the graphene, making the GNR FETs inoperable.

### SUMMARY

Example embodiments relate to methods for fixing defects in graphene, or a graphene nanoribbon, using a laser beam. Other example embodiments relate to methods of manufacturing an electronic device that includes fixing defects in graphene, or a graphene nanoribbon, using a laser beam.

Provided are methods of fixing a defect caused by graphene etching by irradiating a laser beam.

Additional aspects will be set forth in part in the description which follows and, in part, will be apparent from the description, or may be learned by practice of the example embodiments.

According to example embodiments, a method of fixing graphene by using a laser beam includes fixing a defect of a graphene nanoribbon by irradiating the laser beam onto the graphene nanoribbon.

The method may include determining the defect of the graphene nanoribbon. Determining the defect may include measuring a Raman spectrum of the graphene nanoribbon and determining whether a peak of about 1350-cm⁻¹ appears in the graphene nanoribbon.

Fixing the defect may include irradiating the laser beam using an argon laser that oscillates. The laser beam may have a wavelength of about, or at, 514-nm. Fixing the defect may include using a laser power of about 2-mW to about 10-mW. Fixing the defect may include irradiating the laser beam for about 10 minutes to about 15 minutes.

According to example embodiments, a method of manufacturing an electronic device includes providing a graphene layer on a substrate, forming a graphene nanoribbon by patterning the graphene layer, and fixing a defect in the graphene nanoribbon by irradiating a laser beam onto the graphene nanoribbon.

### BRIEF DESCRIPTION OF THE DRAWINGS

These and/or other aspects will become apparent and more readily appreciated from the following description of example embodiments, taken in conjunction with the accompanying drawings of which:

FIGS. 1A and 1B are respectively a cross-sectional view and a plan view illustrating a field effect transistor (FET) that uses a graphene nanoribbon (GNR) as a channel according to example embodiments;

FIG. 2 is a graph illustrating a Raman spectrum of a GNR with respect to whether an edge of the GNR is damaged according to example embodiments;

FIG. 3 is a graph illustrating a relative intensity of a D peak with respect to a G peak in accordance with time elapsed when a laser beam is irradiated onto graphene according to example embodiments;

FIG. 4 is a graph illustrating a relative intensity of the D peak with respect to the G peak in accordance with laser power after graphene is damaged according to example embodiments;

FIG. 5 is a flowchart of a method of fixing a GNR according to example embodiments; and

FIGS. 6A through 6D are cross-sectional views for explaining a method of fixing a GNR during an electronic device manufacturing process according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to methods for fixing defects in graphene, or a graphene nanoribbon, using a laser beam. Other example embodiments relate to methods of manufacturing an electronic device that includes fixing defects in graphene, or a graphene nanoribbon, using a laser beam.

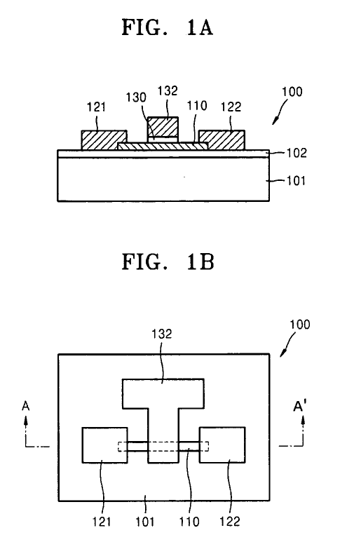

FIGS. 1A and 1B are respectively a cross-sectional view and a plan view illustrating a field effect transistor (FET) that uses a graphene nanoribbon (GNR) as a channel according to example embodiments. FIG. 1B is a plan view of the FET shown in FIG. 1A. FIG. 1A is a cross-sectional view of the FET taken along line A-A′ of FIG. 1B.

Referring to FIG. 1A, a graphene nanoribbon channel 110, a source electrode 121, and a drain electrode 122 are formed on a substrate 101. The substrate 101 may be a silicon substrate. An insulation film 102 is formed between the substrate 101 and the graphene nanoribbon channel 110, the source electrode 121 and the drain electrode 122. The insulation film 102 may be formed of silicon oxide. The source electrode 121 and the drain electrode 122 may be formed of metal (e.g., aluminium (Al), molybdenum (Mo) and similar metals).

The source electrode 121 and the drain electrode 122 may be formed of graphene having a substantially broad width. The source electrode 121, the drain electrode 122, and the graphene nanoribbon channel 110 may be formed of a single graphene layer. The source electrode 121 and the drain electrode 122 may have substantially broad widths by patterning. As such, source electrode 121, the drain electrode 122, and the graphene nanoribbon channel 110 may exhibit conductivity. The graphene nanoribbon channel 110 formed between the source electrode 121 and the drain electrode 122 may have narrow widths, and thus exhibit semiconductor properties.

A gate oxide 130 and a gate electrode 132 are sequentially stacked on the graphene nanoribbon channel 110. The gate electrode 132 may be formed of aluminium (Al) or polysilicon. The gate oxide 130 may be formed of silicon oxide. FIG. 1A shows a top gate type FET.

Referring to FIG. 1B, the graphene nanoribbon channel 110 has a width between about 5-nm and about 20-nm. The graphene nanoribbon channel 110 may be patterned by using an oxygen plasma etching process.

Although the top gate type FET uses a graphene nanoribbon as a channel in FIGS. 1A and 1B, example embodiments are not limited thereto. For example, a bottom gate type FET using the graphene nanoribbon as the channel may be provided. A detailed description thereof is omitted for the sake of brevity.

A surface, or edge, of the graphene nanoribbon may be damaged during a patterning process. In particular, the edge of the graphene nanoribbon may be damaged, which may adversely affect an electronic device. The graphene nanoribbon may not have a hexagonal structure according to a normal SP₂ bonding because carbon is removed from a graphene structure during an etching process, or impurities are coupled to a hexagonal structure of graphene. Removal of carbon, or the coupling of impurities, reduces electron mobility in the graphene nanoribbon and results in loss of a channel function of the graphene nanoribbon. Thus, a FET that uses the graphene nanoribbon as a channel may not operate.

A method of annealing damaged graphene nanoribbon is used to fix the damaged graphene nanoribbon. The annealing method needs a high temperature (e.g., about 1500° C. or above), making it difficult to apply the annealing method to the graphene nanoribbon (in particular, the FET that uses a graphene nanoribbon as a channel).

Example embodiments provide a method of fixing a damaged graphene nanoribbon using a laser beam. An argon laser that oscillates the laser beam having a wavelength of about 514-nm is used.

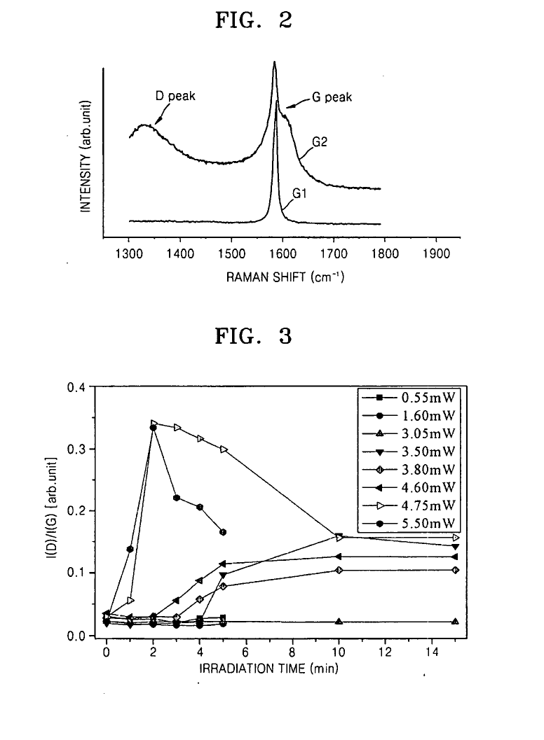

FIG. 2 is a graph illustrating a Raman spectrum of a graphene nanoribbon with respect to whether an edge of the graphene nanoribbon is damaged according to example embodiments.

Referring to FIG. 2, a Raman shift peak of graphene G1 that is not patterned shows a single peak (hereinafter referred to as a “G peak”) at about 1580 cm⁻¹. A Raman shift peak of graphene nanoribbon G2 that is patterned to have a width of about 10-nm shows a peak (hereinafter referred to as a “D peak”) at about 1350 cm⁻¹ in addition to the G peak. Detection of the D peak of the graphene nanoribbon indicates damage to the edge of the graphene nanoribbon during a patterning process.

FIG. 3 is a graph illustrating a relative intensity of the D peak with respect to the G peak in accordance with time elapsed when a laser beam is irradiated onto graphene according to example embodiments.

Referring to FIG. 3, the D peak appears when a laser beam power of about 3.5-mW is irradiated onto the graphene.

When the laser beam power increases to about 4.75-mW, an intensity of the D peak increases and the graphene is further damaged. The D peak is reduced according to the irradiation time of the laser beam onto the damaged graphene. Thus, the damaged graphene is fixed according to the irradiation time of the laser beam. The damaged graphene is fixed when the laser beam is irradiated for about 10 minutes to about 15 minutes.

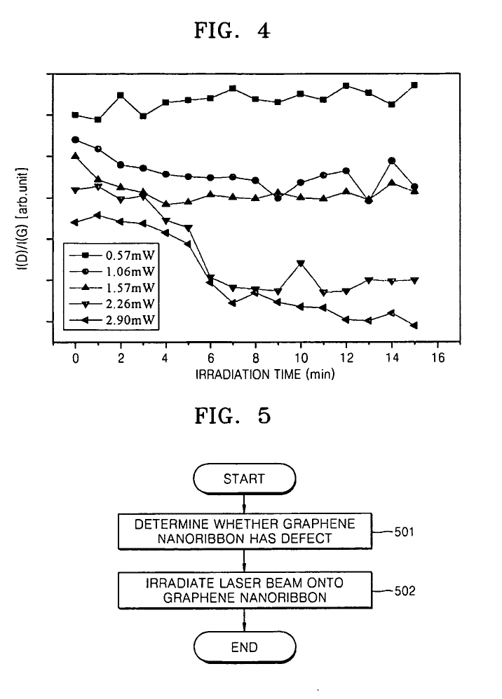

FIG. 4 is a graph illustrating a relative intensity of the D peak with respect to the G peak in accordance with laser power after graphene is damaged according to example embodiments.

Referring to FIG. 4, after the laser beam from an argon laser is irradiated onto the graphene at a wavelength of about 514-nm and a laser power of about 5.8-mW for 2 minutes, the relative intensity of the D peak with respect to the G peak changes according to the laser power and the elapsed time of the laser beam. When the laser beam is irradiated onto the graphene at an initial stage, the D peak appears. This is performed for simulating the damaged nanoribbon, which is formed by etching the graphene. The laser beam is irradiated at a laser power of between about 0.57-mW and about 2.90-mW. The relative intensity of the D peak with respect to the G peak at the beginning (irradiation time=0) in FIG. 4 differs only for distinguishing data from each other.

When the laser power is less than about 1.57-mW, the relative intensity of the D peak with respect to the G peak rarely changes. When the laser power is higher than or equal to 2.26-mW, the relative intensity of the D peak with respect to the G peak decreases in accordance with the irradiation time of the laser beam. Thus, irradiating the laser beam for a period of time of about 7 minutes to about 15 minutes fixes the damaged graphene (i.e., the damaged graphene nanoribbon).

FIG. 5 is a flowchart of a method of fixing a graphene nanoribbon according to example embodiments.

Referring to FIG. 5, a determination is made as to whether the graphene nanoribbon, or the graphene nanoribbon in a FET as a channel, has a defect (501). A defect in the graphene nanoribbon is characterized by a D peak of about 1350 cm⁻¹, which is detected by measuring a Raman spectrum.

If it is determined that the graphene nanoribbon is damaged (501), a laser beam is irradiated onto the graphene nanoribbon (502). When an argon laser beam of a wavelength of about 514-nm is irradiated on the graphene nanoribbon, the laser power is controlled to be higher than a set value (e.g., about 2-mW). When the laser power is lower than about 2-mW, the graphene nanoribbon receives less energy, which results in the damaged graphene nanoribbon not being fixed, or an increase in the time it takes to fix the damaged graphene nanoribbon.

The laser power may be controlled to be lower than 10-mW. When the laser power is controlled to be higher than 10-mW, the graphene nanoribbon may undergo even more damage, making it difficult to fix the damaged graphene nanoribbon even if the laser beam is irradiated thereto.

The method of fixing the damaged graphene nanoribbon using the laser beam may make it easier to restore crystallinity of graphene nanoribbon damaged during an etching process. In particular, a Raman spectroscope detects a defect in the graphene nanoribbon in-situ and fixes the defect using a laser device attached thereto.

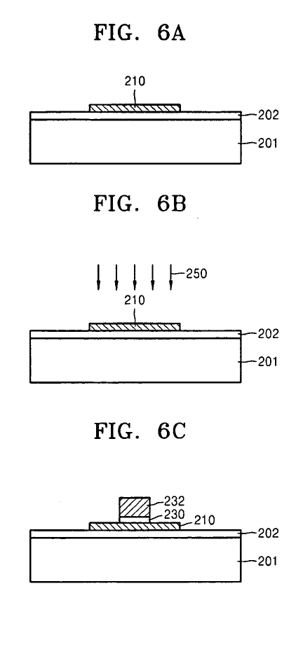

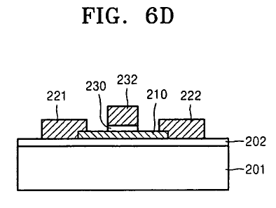

FIGS. 6A through 6D are cross-sectional views for explaining a method of fixing a graphene nanoribbon during an electronic device manufacturing process according to example embodiments.

Referring to FIG. 6A, a graphene nanoribbon channel 210 is formed on a substrate 201. The substrate 201 may be a silicon substrate. An insulation layer 202 (e.g., a silicon oxide layer) may be formed on the substrate 201. The graphene nanoribbon channel 210 may be formed by patterning a graphene layer (not shown) on the insulation layer 202. The graphene layer may be formed by using a chemical vaporization deposition (CVD) method. Alternatively, the graphene layer may be provided by transferring the graphene layer onto the substrate 201.

Referring to FIG. 6B, the graphene nanoribbon channel 210 is fixed using a laser beam 250. An edge, or surface, of the graphene nanoribbon channel 210 may be damaged during a patterning process. An argon laser beam that oscillates the laser beam 250 having a wavelength of about 514-nm may be used. The laser power is about 2-mW to about 10-mW and the laser beam is irradiated for about 10 minutes to about 15 minutes. If the above-mentioned laser beam is irradiated onto the graphene nanoribbon channel 210, a defect of the graphene nanoribbon channel 210 may be fixed.

Referring to FIG. 6C, an insulation layer (not shown) and a conductive layer (not shown) are sequentially formed on the substrate 201 to cover the graphene nanoribbon channel 210. A gate electrode 232 and a gate insulation layer 230 are formed by sequentially patterning the insulation layer and the conductive layer.

Referring to FIG. 6D, a source electrode 221 and a drain electrode 222, which each contact an opposing end of the graphene nanoribbon channel 210, are formed by coating an electrode layer (not shown) on the substrate 201 and patterning the electrode layer.

Although a top gate type FET that uses the graphene nanoribbon channel 210 as a channel is shown in FIGS. 6A through 6D, example embodiments are not limited thereto. For example, a bottom gate type FET may use the graphene nanoribbon channel 210 as the channel.

According to a method of fixing the defect of the graphene by using laser beam, the graphene damaged during the patterning process of the graphene is fixed by irradiating the laser beam thereon.

It should be understood that example embodiments described herein should be considered in a descriptive sense only and not for purposes of limitation. Descriptions of features or aspects within each example embodiment should typically be considered as available for other similar features or aspects in other example embodiments.

What is claimed is:

1. A method of fixing graphene by using a laser beam, the method comprising:
fixing a defect in a graphene nanoribbon by irradiating the laser beam onto the graphene nanoribbon.

2. The method of claim 1, further comprising determining the defect of the graphene nanoribbon.

3. The method of claim 2, wherein determining the defect includes measuring a Raman spectrum of the graphene nanoribbon and determining whether a peak of about 1350 cm⁻¹ appears in the graphene nanoribbon.

4. The method of claim 3, wherein fixing the defect includes irradiating the laser beam using an argon laser that oscillates the laser beam having a wavelength of about 514-nm.

5. The method of claim 4, wherein the laser beam has a wavelength of 514-nm.

6. The method of claim 4, wherein fixing the defect includes using a laser power of about 2-mW to about 10-mW.

7. The method of claim 6, wherein the laser power is about 3.5-mW.

8. The method of claim 6, wherein fixing the defect includes irradiating the laser beam for about 10 minutes to about 15 minutes.

9. A method of manufacturing an electronic device, the method comprising:
providing a graphene layer on a substrate;
forming the graphene nanoribbon according to claim 1 by patterning the graphene layer; and
fixing the defect in the graphene nanoribbon by irradiating the laser beam onto the graphene nanoribbon.

10. The method of claim 9, wherein providing the graphene layer includes transferring the graphene layer onto the substrate.

11. The method of claim 9, wherein providing the graphene layer includes using a chemical vapor deposition (CVD) method.

12. The method of claim 9, wherein patterning the graphene layer includes using an oxygen plasma etching process.

13. The method of claim 9, wherein fixing the defect includes irradiating the laser beam using an argon laser that oscillates the laser beam having a wavelength of about 514-nm.

14. The method of claim 13, wherein the laser beam has a wavelength of 514-nm.

15. The method of claim 13, wherein fixing the defect includes using a laser power of about 2-mW to about 10-mW.

16. The method of claim 15, wherein the laser power is about 3.5-mW.

17. The method of claim 15, wherein fixing the defect includes irradiating the laser beam for about 10 minutes to about 15 minutes.
